(19) United States
(12) Patent Application Publication
(10) Pub. No.: US 2024/0375592 A1
(43) Pub. Date: Nov. 14, 2024

(54) SMART CARGO BOX AND METHODS

(71) Applicant: Eric Prue, Marquette, MI (US)

(72) Inventor: Eric Prue, Marquette, MI (US)

(21) Appl. No.: 18/660,670

(22) Filed: May 10, 2024

Related U.S. Application Data
(60) Provisional application No. 63/465,274, filed on May 10, 2023.

(51) Int. Cl. B60R 9/058; H05K 5/00; H05K 5/02

(52) U.S. Cl. CPC B60R 9/058; H05K 5/0086; H05K 5/0204; H05K 5/0221; H05K 5/0226

(57) ABSTRACT

A smart cargo box for the transport of cargo on the roof rails of a vehicle. The smart cargo box comprises a complementary fitting upper clam shell and a lower clam shell that define an internal space that can be utilized for storage. A power stack including a battery and power module are coupled to an electric nest that is secured to an interior face of the lower clam shell. A camera coupled to the electric nest can capture photos of anyone attempting to enter the internal space. A lock controls entry to the internal space with the lock comprising a lock sensor to sense entry to the internal space.

### CROSS REFERENCE TO RELATED APPLICATIONS

This application claims priority to Provisional Patent Application No. 63/465,274 filed May 10, 2023, the entire disclosure of which is hereby incorporated by reference and relied upon.

### BACKGROUND OF THE INVENTION

Field of the Invention. The invention relates generally to cargo box systems and more particularly to motor vehicle mounted smart cargo box systems and methods, and portable power.

Prior art Motor vehicle mounted cargo box systems have predominantly been used to provide additional storage space during transit while keeping the goods stored inside clean, dry, and secure. There is a need however, for these systems to do more. For example, can they provide additional security features? Can they provide portable power? Portable power systems have traditionally been in the form of gas-powered systems. These systems are loud, heavy, create air pollution, and require the purchase of fossil fuels to operate. In addition, these systems are not always reliable, and are often difficult to start especially if the fuel is old or the engines have been sitting for extended periods.

What is needed is a cargo box system that integrates portable power within the cargo box that can be removed and used as needed once reaching a destination. What is needed is a cargo box system that integrates additional safety features to keep the goods inside the cargo box safe.

### SUMMARY OF THE INVENTION

Disclosed herein is a smart cargo box comprising an integrated portable power system and additional smart features for protecting goods stored within the smart cargo box.

In one form, the smart cargo box is mounted to a motor vehicle.

In one form, the smart cargo box comprises a power stack that includes an electric nest that is fixed to a lower clam shell.

In one form, the power stack comprises a stack of components that can be interlocked with each other including one or more intermediate batteries and a power module at a superior end releasably coupled to the electric nest.

In one form, a variety of electric accessories can be connected to the power system either to supply power to the portable power system thereby charging the battery stack, or to provide power to one or more connected electronic devices for charging or operation.

In one form, by detaching the power module and one or more batteries from the electric nest, the system can then be used as a completely portable power station that can be taken to remote locations such as in the middle of the woods. By attachment of a portable solar panel, the power system will recharge itself.

In one form, a smart cargo box utilizes a power stack secured in the internal space of the smart cargo box.

In one form, a smart cargo box is electrically coupled to a power stack secured elsewhere on a vehicle such as in a truck bed or trunk. In this case, conductors are routed to the smart cargo box from the power stack. Apertures through body panels or through the cargo box can be used to route necessary conductors.

In one form, a smart cargo box comprises an upper clam shell and a lower clam shell that when coupled create an internal space in which goods can be stored and transported.

In one form, the upper clam shell comprises a sky face that faces upwards when the smart cargo box is in the closed operational configuration, and an upper shell interior face opposite the sky face that faces the internal space.

In one form, a solar panel can be affixed to the skyface and electrically coupled to the electrical nest.

In one form, the lower clam shell comprises a down face that faces downward in the operational configuration, and a lower shell interior face that faces upward in the internal space.

In one form, the perimeter opening of the upper clam shell is larger than the lower clam shell such that when the perimeter openings are mated, the larger upper shell prevents weather elements from entering internal space.

In one form, weather stripping is used at this junction of the perimeter openings.

In one form, the upper clam shell is pivotably attached to the lower clam shell along common edges by clam hinge whereby the upper clam shell can pivot upwards to open. The clam hinge can assume a variety of forms known in the art such as for example, pinned hinges of metals or polymers, flexible polymers or polymer weaves, or natural materials such as leathers.

In one form, a plurality of rail clamps extend from the down face and releasably fix themselves to cross bars mounted to a vehicle roof via cross bar fixators.

In one form, the rail clamps comprise adjustable opposing jaws that can open to fit over a crossbar and close about a crossbar to secure the smart cargo box to the vehicle.

In one form, a camera with onboard or removable memory is mounted to the upper shell interior face. When the upper clam shell is opened, the lens of the camera faces the individual responsible for this action.

In one form, various sensors are included in the system such as a motion sensor that detects motion of the smart cargo box and an upper shell position sensor that senses the open or closed position of the upper clam shell.

In one form, a lock sensor used in conjunction with a lock senses when a key is inserted into the lock and the position of lock latch that secures the upper clam shell in a locked position. Sensor signals from the lock are carried by lock conductor.

In one form, the sensors, cameras and other electrical devices can be powered by the power stack through one or more conductors.

In one form, the smart cargo box can include a microprocessor that considers the input from the various sensors.

In one form, upon sensing that the upper clam shell was opened without unlocking the lock, the microprocessor can actuate the camera to begin taking pictures or video of the individual(s) gaining unauthorized entry to the smart cargo box.

In one form, the camera begins recording when the lock is not opened and the motion sensors detect motion.

In one form, conductor clamps can be used within the smart cargo box to secure the conductors to the smart cargo box.

In one form, the electric nest is fixed to the lower shell interior face.

In one form, the power module and one or more batteries can be removed to provide truly portable power away from the motor vehicle such at a campsite.

In one form, portability of the power module is achieved by releasing the latch holding the first battery to electric nest as described previously.

In one form, the batteries can be recharged while the power module and batteries remain seated within the smart cargo box, or upon their removal from a power source such as a portable solar panel or other electrical supply source.

In one form, a vehicle with a smart cargo box will have a power stack contained in internal space as well as a power stack mounted elsewhere on the vehicle. Through conductors, these power stacks can be configured to cooperate wherein one power stack can receive or supply power to the other power stack as needed.

### BRIEF DESCRIPTION OF THE SEVERAL VIEWS OF THE DRAWINGS

These and other features and advantages of the present invention will become more readily appreciated when considered in connection with the following detailed description and appended drawings, wherein each drawing is according to one or more embodiments shown and described herein, and wherein:

FIG. 1 depicts a perspective view of a motor vehicle with a power stack coupled to an electric nest that is fixed to the vehicle;

FIG. 2 depicts a close up perspective view of the power stack and electric nest of FIG. 1;

FIG. 3 depicts a perspective view of the power stack and electric nest of FIG. 1 and various electrical ports;

FIG. 4 depicts a perspective view of the power stack and electric nest of FIG. 1 and various conductors extending therefrom;

FIG. 5 depicts a perspective view of the power stack and electric nest of FIG. 1 noting various batteries;

FIG. 6 depicts a perspective view of the power stack and electric nest of FIG. 1 and highlighting latches used to secure the batteries;

FIG. 7 depicts a closeup perspective view of a latch utilized to releasably secure portions of the power stack together;

FIG. 8 depicts a bottom perspective view of the electric nest of FIG. 1;

FIG. 9 depicts a top perspective view of the electric nest of FIG. 1;

FIG. 10 depicts a bottom perspective view of a battery utilized in the power stack of FIG. 1;

FIG. 11 depicts a side view of a battery utilized in the power stack of FIG. 1;

FIG. 12 depicts a top perspective view of a battery utilized in the power stack of FIG. 1;

FIG. 13 depicts a bottom perspective view of a battery and its toe lip utilized to interlock members of the power stack of FIG. 1;

FIG. 14 depicts a side view of two batteries latched together of the power stack of FIG. 1;

FIG. 15 depicts a side view of a power stack in one step of engaging and disengaging the power stack to an electric nest;

FIG. 16 depicts a side view of a power stack in one step of engaging and disengaging the power stack to an electric nest;

FIG. 17 depicts a side view of a power stack in one step of engaging and disengaging the power stack to an electric nest;

FIG. 18 depicts a side view of a power stack in one step of engaging and disengaging the power stack to an electric nest;

FIG. 19 depicts a side view of a power stack in one step of engaging and disengaging the power stack to an electric nest;

FIG. 20 is a graphic depicting the electrical relationship between components of a power stack and electric nest;

FIG. 21 is a graphic depicting the electrical relationship between a power module and one or more stacked batteries;

FIG. 22 is a graphic depicting mating a battery from the system to an electric device;

FIG. 23 depicts a perspective view of a smart cargo box secured to cross bars of the roof of a vehicle;

FIG. 24 depicts a perspective view of the smart cargo box of FIG. 23 in an opened configuration;

FIG. 25 depicts a perspective view of a lock with a lock sensor used with the smart cargo box;

FIG. 26 depicts a perspective view of a camera used within the smart cargo box of FIG. 23;

FIG. 27 depicts a perspective view of a conductor clamp utilized in embodiments of the smart cargo box to manage the conductors;

FIG. 28 depicts a perspective view of a power stack coupled to an electric nest inside the smart cargo box of FIG. 23.

### DETAILED DESCRIPTION OF SELECTED EMBODIMENTS OF THE INVENTION

Select embodiments of the invention will now be described with reference to the Figures. Like numerals indicate like or corresponding elements throughout the several views and wherein various embodiments are separated by letters (i.e. 100, 100B, 100C). The terminology used in the description presented herein is not intended to be interpreted in any limited or restrictive way, simply because it is being utilized in conjunction with detailed description of certain specific embodiments of the invention. Furthermore, embodiments of the invention may include several novel features, no single one of which is solely responsible for its desirable attributes or which is essential to practicing the invention described herein.

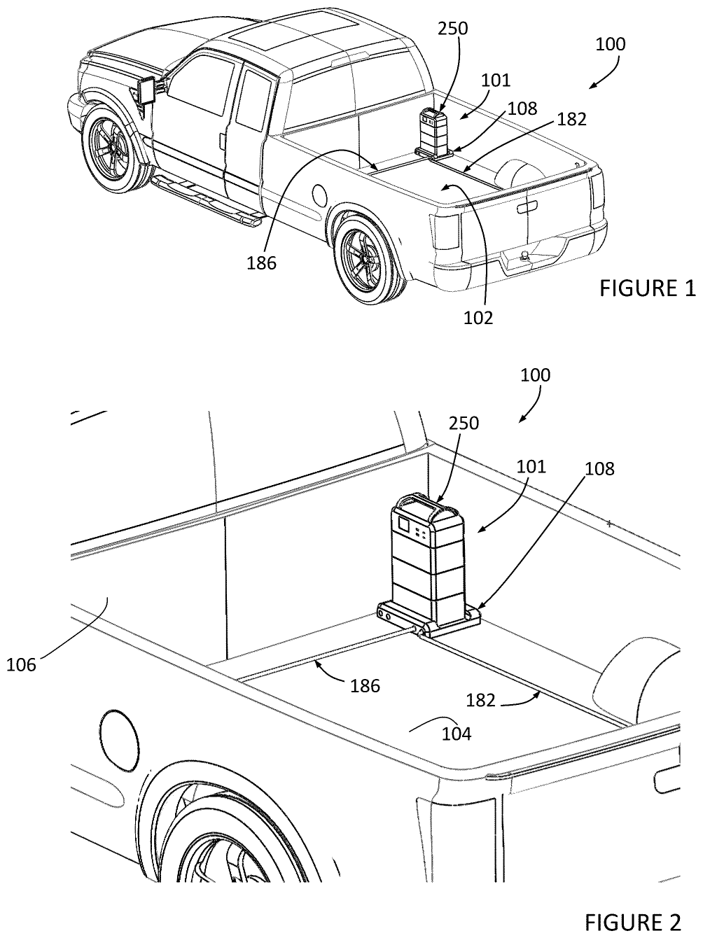

FIGS. 1-22 depicts a power stack as can be mounted to a vehicle via an electric nest. Later figures depict a power stack integrated into a smart cargo box with additional features. FIG. 1 depicts a motor vehicle 100 with a power stack 101. The power stack 101 is secured to a convenient location on a motor vehicle such as on the vehicle floor 104 within a truck bed 102 next to the vehicle wall 106 of the bed or in the trunk of a vehicle. The power stack 101 comprises a power module 250 that releasably mates with one or more batteries. For example, as illustrated in an operational configuration in FIG. 5, the power stack 101 comprises an electric nest 108 mounted to the vehicle that serves as a secure base for first battery 200, second battery 202, third battery 204, and terminating in power module 250.

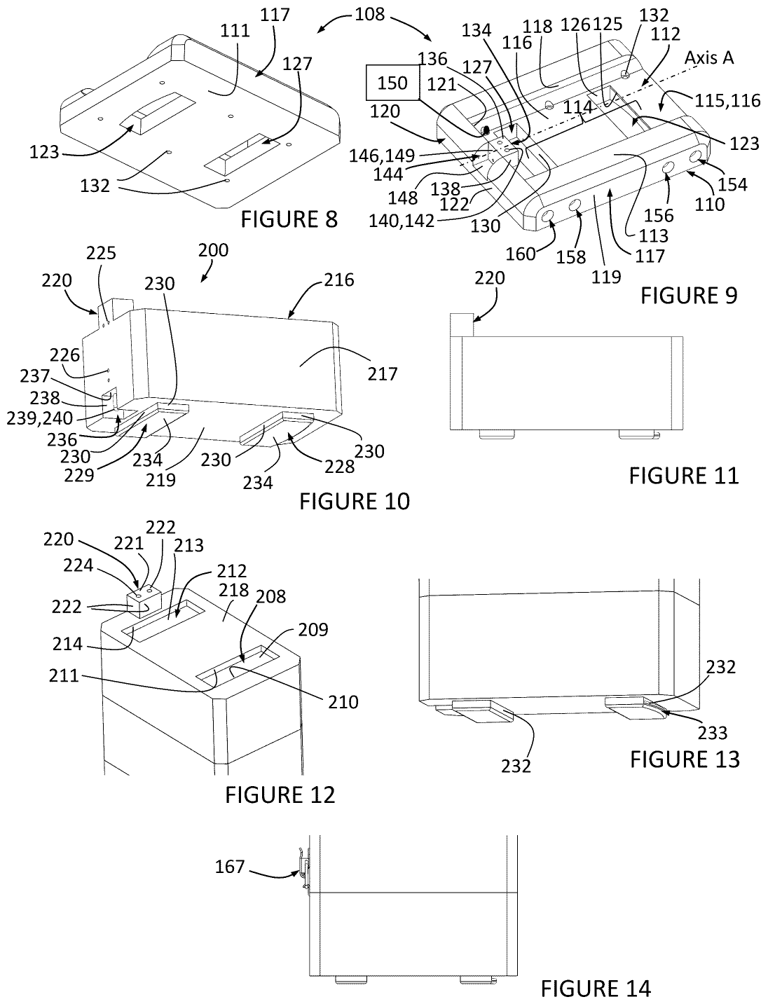

In this embodiment (FIG. 8-9), the electric nest 108 comprises a generally square or rectangular nest body 110 having a downward facing mate face 111 and an upward facing base face 113. A battery inset 112 descends downward partially into the nest body 110 from the base face 113 and stopping at foot receiver floor 115 with floor face 116 thereon. Extending into floor face 116 is a foot receiver 114 for receiving portions of a battery for removable fixation to the electric nest 108. The foot receiver 114 comprises a heel receiver 127 spaced from a toe receiver 123 with both extending through the floor face 116. In some embodiments, the toe receiver and foot receiver extend only partially into the nest body, however, in this embodiment, they extend all the way through the nest body 110 as depicted in FIG. 8.

Surrounding the battery inset 112 on 2 sides are opposing foot receiver side walls 117 which are joined by foot receiver center wall 120 forming a generally U-shaped upstanding wall. Inner faces 118 on the foot receiver side walls face central axis A, whereas, outer faces 119 on the foot receiver side walls face away from central axis A. The battery inset 112 is also defined by inner face 121 on foot receiver center wall 120 facing towards the battery inset with outer surface 122 facing away from the battery inset.

The heel receiver 127 is defined by a heel receiver face 130 extending between floor face 116 and mate face 111 (or an upward facing heel receiver floor 128 if present). In this embodiment, the heel receiver has a generally rectangular profile, but other profiles can be used. The toe receiver 123 is defined by a toe receiver face 126 extending between floor face 116 and mate face 111 (or an upward facing toe receiver floor 124 if present). At one end of the toe receiver 123 is a toe receiver roof 125 that partially extends over the toe receiver 123 to block a toe lip 233 of a battery mated to the electric nest 108 to assist securing the battery to the electric nest.

A plurality of fixation holes 132 extend between the floor face 116 and mate face 111 for housing fasteners 150 that secure the electric nest 108 to a portion of a motor vehicle 100. Alternatively, the fixation holes can extend between base face 113 and mate face 111.

In this embodiment, a nest electrical pod 134 extends upward from floor face 116 and terminates at pod upper face 136. The electrical pod 134 in this embodiment is in a generally square block form, but can assume a variety of forms that complement the respective feature on a mating battery. Here, the nest electrical pod 134 is defined by pod side faces 138 extending between pod upper face 136 and floor face 116. Extending into pod upper face 136 is first pod contact 140 and second pod contact 142 which again complement the respective electrical features on a mating battery (i.e. first battery 200). Aligned with electrical pod 134 and extending through foot receiver center wall 120 to electrical pod 134 is latch window 144 which is defined latch side faces 148 and latch face 146 adjacent to the electrical pod. Latch mount holes 149 extend into latch face 146 to house fasteners for securing a lower latch portion 176 to latch face 146.

Integrated into the electric nest 108, are a plurality of electrical ports for the intake of electrical signals or power and/or the output of electrical signals or power. In the embodiment of FIG. 9, the electrical ports extend through outer face 119 into foot receiver side wall 117. These electrical ports however, can be located on other faces of the electrical nest such as base face 113 or even through mate face 111 when porting conductors behind walls such as the floor of a truck bed. In this embodiment, first electrical port 154, second electrical port 156, third electrical port 158, and fourth electrical port 160 extend through outer face 119 (and any number of additional electrical ports such as for example a fifth electrical port 162 and sixth electrical port 164). Electrical conductors extending from these ports can use any electrical connectors known in the art for this purpose for fixed or releasable connection. Example of electrical conductors are illustrated in at least FIG. 1 whereby first conductor 182 is depicted having a first conductor first end 183 (FIG. 4) and a second conductor second end 184 (not shown), and whereby second conductor 186 is depicted having a second conductor first end 187 and a second conductor second end 188 (not shown). Similarly other electrical ports (not shown) can be utilized using respectively for example, a third conductor 190 (FIG. 5) having a third conductor first end 191 and a third conductor second end 192, and a fourth conductor 194 having a fourth conductor first end 195 and a fourth conductor second end 196 etc.

Each electrical port and conductor can be configured to have any number of sub conductors contained within. For example, the first conductor can include a first wire, second wire, third wire, fourth wire etc. contained inside. The electrical ports can be configured to receive electrical energy such as for example from a solar panel, electrical outlet, or battery. Conversely, the electrical ports can be configured to supply electrical energy of various voltage and amperage such as for example, to run an appliance, or to charge an electric bike, a cell phone, or other motorized electric device.

As discussed previously, power stack 101 comprises a power module 250 mated to a series of interconnected batteries and terminating with the electrical nest 108. The power module can comprise a variety of features that may be known in the prior art. For example, in one embodiment, the power module is in the form of a VOLTAFREE VFP 1000 power station. The power module 250 comprises a module body 252 that in this embodiment is substantially block like although other profiles can be used that are conducive to mating with a battery. The power module 250 in an operational configuration as shown, comprises a superior surface 254 facing upward and an inferior surface 255 facing downward. Projecting from the inferior surface 255 is a power toe 256 and a power heel 257. The power toe and power heel are defined by lateral faces 258 facing laterally, a rear face 259 facing rearward, and a front face 260 facing the front. A toe lip 261 extends from one end of the power toe for interlocking with a battery. These features on the inferior surface are not shown but replicate the interlock construction of the complementing battery depicted in FIG. 10.

The power module 250 comprises an operational face on which various electrical ports and power display are located. For example, the electrical ports can include DC supply ports 264 such as a USB-C 265, a 5V supply 266, a Qualcomm USB 5V quick charge 267, and a 12V supply 268 such as a car plug. The electrical ports can include an AC supply port 269 such as a 110V electrical outlet and can also include a power input port 270 such as to receive energy from a solar panel.

Some embodiments of the power module 250 include a power display 272 to display various information such as the input power 273 that is received such as from a solar panel, the output power 274 that is being delivered such as to a connected electric heater, a charge monitor 275 to indicate the percentage of battery charge wherein 100% indicates full charge, a display control button 276 to turn the display on and off, a fuse 277 to protect circuits, an output time display 278 indicating how long the battery power will last at the current output, an input time display 279 indicating the amount of time until full charge, and an on/off control 280 to power or shut down the power module.

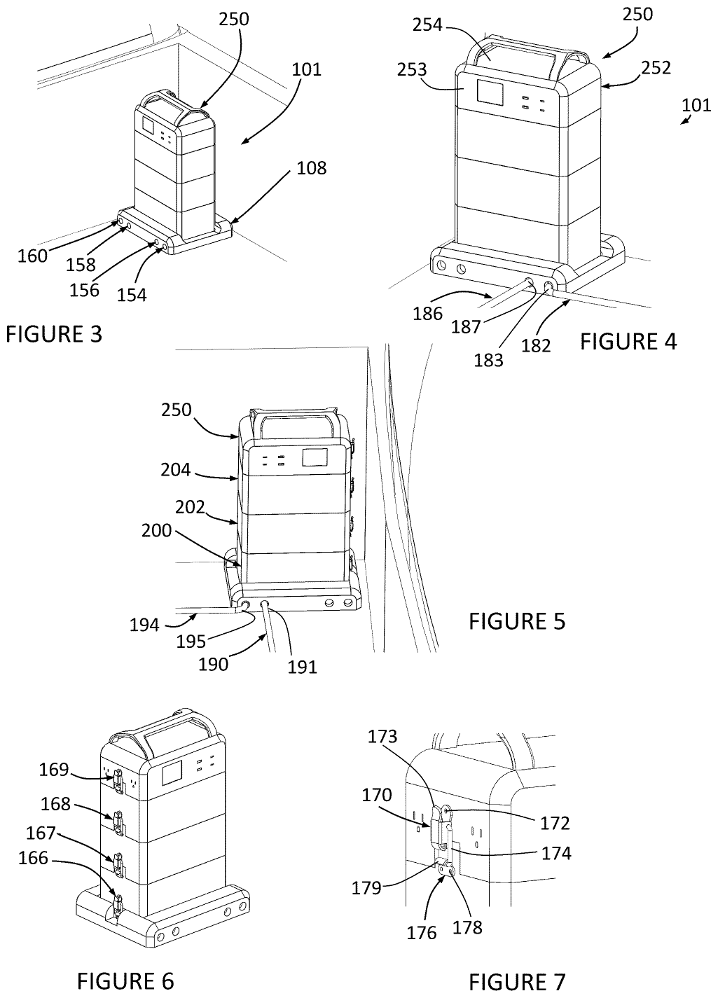

The operational configuration depicted in FIGS. 3-7 includes one or more stacked batteries positioned between power module 250 and electric nest 108. Depicted here is electric nest 108 coupled with first battery 200, which is coupled with second battery 202, which is coupled with third battery 204, which is coupled with power module 250. These components have a releasable interlock architecture providing releasable fixation between the components. In this embodiment, the releasable interlock architecture is in the form of foot, heel, and toe features discussed herein. In addition, a secondary fixation system can be used. For example, a first latch 166 can be used to lock together electric nest 108 and first battery 200, whereas a second latch 167 can be used to lock together first battery 200 to second battery 202, and whereas a third latch 168 can be used to lock together second battery 202 to third battery 204, and whereas a fourth latch 169 can be used to lock together third battery 204 to power module 250. Other types of interlocking mechanisms known in the art can be used for this same purpose. Here the latches comprise a pivoting upper latch portion 170 having an upper latch handle 173 for activating with a user's fingers. A restraint arm 174 extends downward from the upper latch portion for engaging with a lower latch catch 179 of a lower latch portion 176. Upper latch fixation holes 172 extend through an upper latch mount face 171 to house fasteners to hold the upper latch to a battery or power module. Similarly, lower latch fixation holes 178 extend through a lower latch mount face 177 to house fasteners to hold the lower latch to a battery or power module.

The batteries can assume a variety of profiles provided they have architecture conducive to releasably mating to some form of electric nest 108 and power module 250. FIGS. 10-14 provide various views of one style of battery depicted here as first battery 200. Battery 200 comprises a substantially block like battery body 216 having an external face 217 facing laterally from the sides, a superior face 218 facing superiorly, and an inferior face 219 facing inferiorly. A battery electrical pod 220 extends upward from superior face 218 on one end and is defined by pod side faces 222 on the sides and terminating in pod upper surface 221 superiorly. Extending into superior face 218 is first terminal 223 and second terminal 224 which are essentially positive and negative terminals for transmitting power from and to the battery. On an external face 217 of the battery electrical pod 220 are superior latch fixation holes 225 to receive fasteners to secure a lower latch portion 176 thereto. Also, on external face 217 is inferior latch fixation holes 226 to receive fasteners to secure an upper latch portion 170 thereto.

Extending inferiorly from inferior face 219 of the battery is battery heel 229 and battery toe 228 which are spaced from each other. The battery heel and battery toe are defined by lateral faces 230 facing laterally, rear faces 231 facing rearward, end face 234 facing downward, and front faces 232 facing frontward. A toe lip 233 extends laterally from one end of the battery toe 228 for engaging a complementary electric nest or another battery.

Located directly inferior to the battery electrical pod 220 is pod receiver 236 which is inset into battery body 216 at the intersection of the external face 217 and inferior face 219. Pod receiver 236 is defined by guide faces 238 facing radially, and terminal face 237 facing battery electrical pod 220. Projecting outward from terminal face 237 are first contact 239 and second contact 240 which are configured for electrical connection to either electrical nest 108 or another battery.

Inset into superior face 218 of the batteries is battery toe receiver 208 and battery heel receiver 212. In this embodiment, battery toe receiver 208 is generally rectangular and is defined by radially facing battery toe receiver face 211 which terminates at upward facing battery toe receiver floor 209. Battery toe receiver roof 210 extends below superior face 218 to house toe lip 233 when interlocking these parts. Battery heel receiver 212 is generally rectangular and is defined by radially facing battery heel receiver face 214 which terminates at upward facing battery heel receiver floor 213.

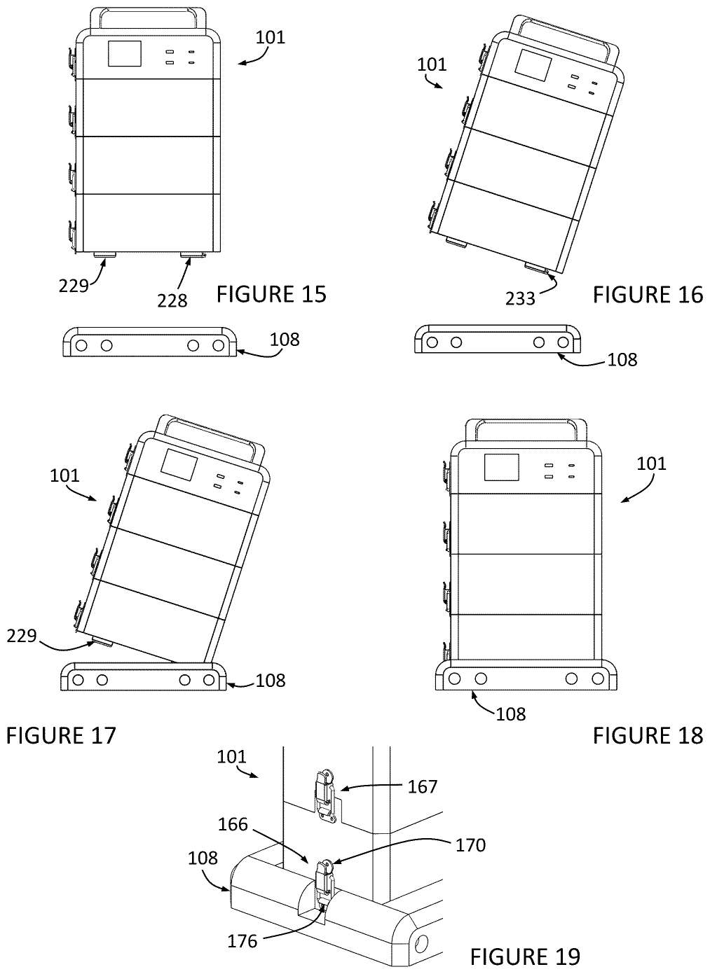

FIGS. 15-19 depict a method for engaging and disengaging the power stack 101 to electric nest 108. The steps include aligning the power stack above electric nest 108 (FIG. 15). Tilting the power stack 101 such that the exposed toe lip 233 is angled downward (FIG. 16). Engaging the toe lip 233 in the toe receiver 123 of the electric nest 108 (FIG. 17). Lowering the power stack such that the battery heel 229 is seated in the heel receiver 127 of the electric nest 108 (FIG. 18), and latching the restraint arm 174 to the lower latch portion 176 thereby securing the power stack 101 (FIG. 19). Removal of the power module 250 and one or more batteries from remaining batteries and electric nest 108 is a reversal of these steps.

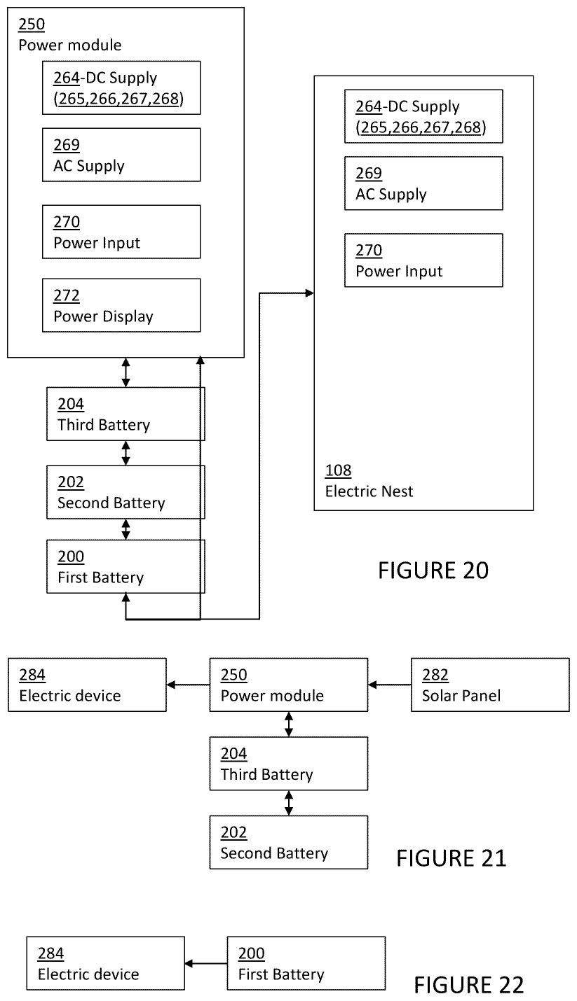

The portable power system described herein is a convenient solution to proving portable power practically anywhere. FIG. 20 is a graphic representing one embodiment of the electronic relationship between the power module 250, the batteries (200,202,204), and the electric nest 108 when attached to the vehicle. Of course, various power input devices such as a solar panel can be attached to provide power to the system and charge the battery. In addition, various electric devices such as an electric refrigerator can be electrically connected to the supply port to operate.

FIG. 21 is a graphic representing one embodiment of the electronic relationship between the power module 250, and one or more stacked batteries. The system depicted is completely portable in that it can be removed from the electric nest that is fixed to a vehicle and transported to remote places. Here the system can power or charge electronic devices 284, and can also renew its own power by attachment of a portable solar panel 282 to a power input on the power module.

FIG. 22 is a graphic representing one embodiment whereby a battery from the system, such as first battery 200 is removed and mated directly to an electric device 284 such as a power tool. Later the battery is reintegrated into the power configurations of FIG. 20 and FIG. 21 for recharging.

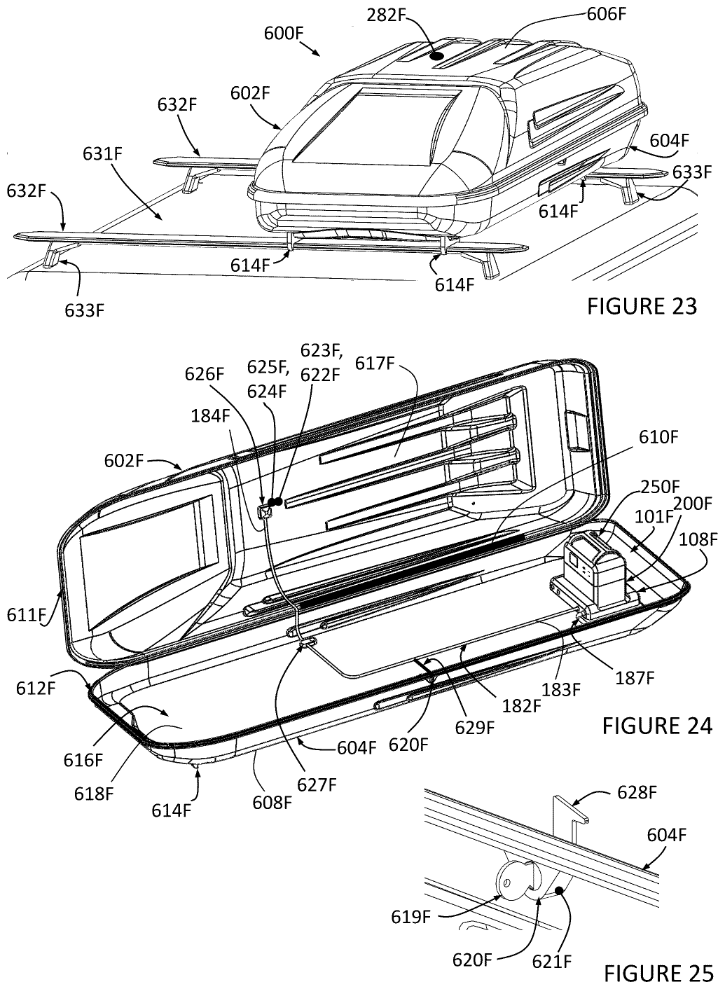

FIGS. 23-24 depicts one embodiment of a smart cargo box 600F utilizing a power stack 101F, as introduced previously, that is secured in the internal space 616F of the smart cargo box. In alternative embodiments, the smart cargo box 600F is electrically coupled to a power stack 101 secured elsewhere on a vehicle 100 such as in a truck bed or trunk as presented in FIG. 2. In this case, conductors are routed to the smart cargo box from the power stack 101. Apertures through body panels or through the cargo box can be used to route necessary conductors.

Smart cargo box 600F comprises an upper clam shell 602F and a lower clam shell 604F that when coupled create an internal space 616F in which goods can be stored and transported. In some embodiments, sky face 606F comprises a solar panel affixed thereon that is electrically joined to electric nest 108F for charging batteries of power stack 101F. The upper clam shell 602F comprises a sky face 606F that faces upwards when the smart cargo box 600F is in the closed operational configuration, and an upper shell interior face 617F opposite the sky face that faces the internal space. The lower clam shell 604F comprises a down face 608F that faces downward in the operational configuration, and a lower shell interior face 618F that faces upward in the internal space 616F. The perimeter opening of the upper clam shell is larger than the lower clam shell such that when the perimeter openings are mated, the larger upper shell prevents weather elements from entering internal space 616F. Weather stripping can also be used at this junction. The upper clam shell 602F is pivotably attached to the lower clam shell 604F along common edges by clam hinge 610F whereby the upper clam shell 602F can pivot upwards to open. A plurality of rail clamps 614F extend from down face 608F and releasably fix themselves to cross bars 632F mounted to a vehicle roof 631F via cross bar fixators 633F.

As noted in FIG. 24, a camera 626F with onboard or removable memory 625F is mounted to the upper shell interior face 617F. When the upper clam shell 602F is opened, the lens of the camera faces the individual responsible for this action. Various sensors can be included in the system such as a motion sensor 623F that detects motion of the smart cargo box 600F and an upper shell position sensor 622F that senses the open or closed position of the upper clam shell 602F. A lock sensor 621F (FIG. 25) used in conjunction with a lock 620F senses when a key 619F is inserted into the lock and the position of lock latch 628F that secures the upper clam shell 602F in a locked position. Sensor signals from the lock 620F are carried by lock conductor 629F.

The sensors, cameras and other electrical devices can be powered by power stack 101 through one or more conductors such as first conductor 182F. In addition, the smart cargo box 600F can include a microprocessor 624F that considers the input from the various sensors. In one embodiment, upon sensing that the upper clam shell 602F was opened without unlocking lock 620F, the microprocessor can actuate camera 626F to begin taking pictures or video of the individual(s) gaining unauthorized entry to the smart cargo box. In another form, the camera begins recording when the lock is not opened and the motion sensors detect motion. Conductor clamps 627F can be used within the smart cargo box to secure the conductors to the smart cargo box.

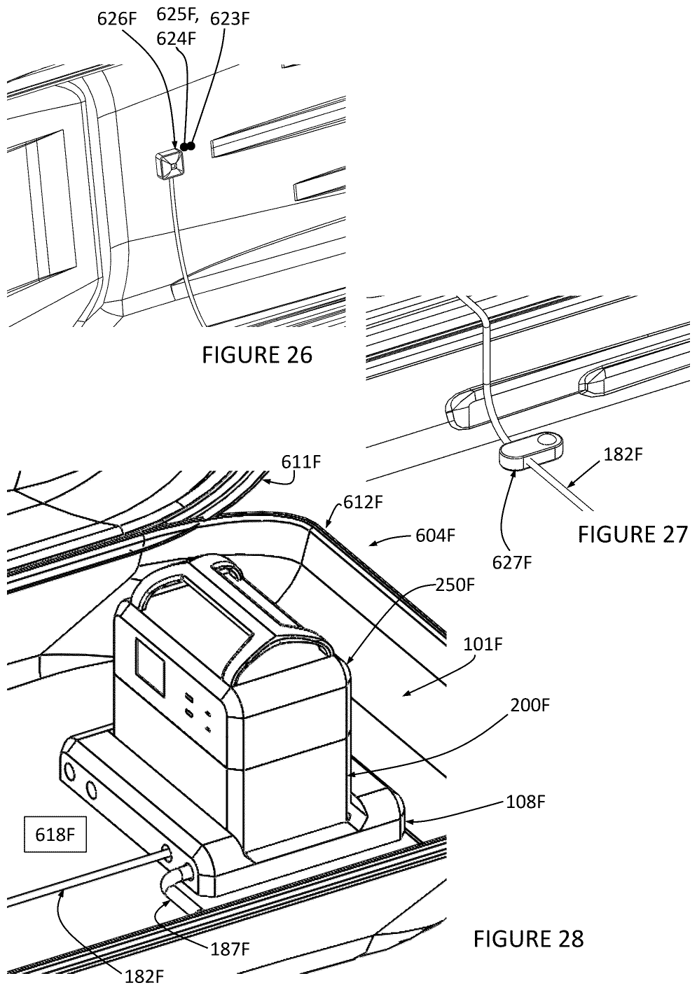

FIGS. 26-28 depict enlarged views of various components within a smart cargo box 600F. As noted in the FIG. 28 embodiment, the electric nest 108F is fixed to the lower shell interior face 618. However, the power module 250 and one or more batteries such as first battery 200F can be removed to provide truly portable power away from the motor vehicle such at a campsite. This is achieved by simply releasing the latch holding the first battery 200F to electric nest 108F as described previously. The batteries can be recharged while the power module and batteries remain seated within the smart cargo box 600F, or upon their removal from a power source such as a portable solar panel 282 or other electrical supply source.

In some embodiments, a vehicle with a smart cargo box 600F, will have a power stack 101F contained in internal space 616F as well as a power stack 101 mounted elsewhere on the vehicle as depicted in FIG. 2. Through conductors, these power stacks can be configured to cooperate wherein one power stack can receive or supply power to the other power stack as needed.

It is noted that the terms “substantially” and “about” and “generally” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

The foregoing invention has been described in accordance with the relevant legal standards, thus the description is exemplary rather than limiting in nature. Variations and modifications to the disclosed embodiment may become apparent to those skilled in the art and fall within the scope of the invention.

What is claimed is:

1. A smart cargo box comprising:
an upper clam shell;
said upper clam shell having an upper shell interior face;
said upper clam shell having an upper closure rim;
a lower clam shell;
said upper clam shell having an lower shell interior face;
said lower clam shell having a lower closure rim;
said upper clam shell and said lower clam shell defining an internal space when said smart cargo box is closed with said upper closure rim engaging said lower closure rim;
a power module for regulating portable power;
at least one battery;
an electric nest;
a camera; and,
a lock operable to secure said upper clam to said lower clam shell thereby securing entry into said internal space.

2. The smart cargo box of claim 1 wherein said electric nest is secured to said lower shell interior face.

3. The smart cargo box of claim 1 wherein said camera is secured to said upper shell interior face.

4. The smart cargo box of claim 1 further comprising:
a first conductor;
wherein said first conductor extends between said camera and said electric nest.

5. The smart cargo box of claim 1 further comprising:
a plurality of rail clamps; and,
wherein said rail clamps are operable for releasable fixation to cross bars on the roof of a vehicle.

6. The smart cargo box of claim 1 further comprising:
a lock;
a key;
said lock comprising a lock sensor; and,
wherein said lock sensor senses attempted entry into said internal space without use of said key.

7. The smart cargo box of claim 1 further comprising:
removable memory; and,
wherein said removable memory records camera images when said upper clam shell is moved to an opened position.

8. The smart cargo box of claim 1 further comprising:
at least one hinge;
said hinge fixed extending across said upper closure rim and said lower closure rim;
said hinge fixed to said upper clam shell and said lower clam shell; and,
wherein said hinge is operable to provide articulation between said clam shells.

9. The smart cargo box of claim 1 further comprising:
a motion sensor;
wherein said motion sensor senses movement of said upper clam shell.

10. The smart cargo box of claim 1 further comprising:
a microprocessor;
wherein said microprocessor processing input from one or more sensors associated with said smart cargo box.

11. The smart cargo box of claim 1 wherein said battery and said power module are removeable from said electric nest and operable to provide remote power.

12. The smart cargo box of claim 1 further comprising:
a solar panel;
wherein solar panel provides energy to charge said battery through said power module.

13. The smart cargo box of claim 1 wherein said electric nest is fixed in position at a posterior end of said lower clam shell in said internal space.

14. A smart cargo box comprising:
an upper clam shell;
said upper clam shell having an upper shell interior face;
a lower clam shell;
said upper clam shell having a lower shell interior face;
said upper clam shell and said lower clam shell defining an internal space when said smart cargo box is closed;
a power module for regulating portable power;
at least one battery;
an electric nest;
a camera; and,
wherein said power module, said at least one battery, said electric nest and said camera are disposed within said internal space during operation.

15. A smart cargo box of claim 14 further comprising:
a lock operable with a lock sensor to secure said upper clam to said lower clam shell thereby securing entry into said internal space.

16. The smart cargo box of claim 14 wherein said electric nest is secured to said lower shell interior face.

17. The smart cargo box of claim 14 wherein said camera is secured to said upper shell interior face.

18. The smart cargo box of claim 14 further comprising:
a plurality of rail clamps; and,
wherein said rail clamps are operable for releasable fixation to cross bars on the roof of a vehicle.

19. The smart cargo box of claim 14 further comprising:
a lock;
a key;
said lock comprising a lock sensor, and,
wherein said lock sensor senses attempted entry into said internal space without use of said key.

20. The smart cargo box of claim 14 further comprising:
removable memory; and,
wherein said removable memory records camera images when said upper clam shell is moved to an opened position.
